(19) United States
(12) Patent Application Publication
(10) Pub. No.: US 2011/0094676 A1
(43) Pub. Date: Apr. 28, 2011

(54) METHOD FOR CLUING FLEXIBLE CIRCUIT BOARDS TO POLYMER MATERIALS FOR PARTIAL OR COMPLETE STIFFENING

(75) Inventors: Marc Husemann, Hamburg (DE); Frank Hannemann, Hamburg (DE); Markus Brodbeck, Hamburg (DE)

(73) Assignee: tesa SE, Hamburg (DE)

(21) Appl. No.: 12/864,637

(22) PCT Filed: Jan. 21, 2009
(86) PCT No.: PCT/EP2009/050666

§ 371 Date: Nov. 30, 2010

(30) Foreign Application Priority Data
Jan. 28, 2008 (DE) 10 2008 006 390.8

(51) Int. Cl. H05K 3/00

(52) U.S. Cl. 156/306.6

(57) ABSTRACT

A method for producing circuit boards, comprising a process for modifying a flexible circuit board, in particular for the stabilization thereof, characterized by at least the following method steps: a) providing a planar formation (“reinforcement plate”) having lower flexibility than that of the flexible circuit board, b) hot laminating an adhesive film, which can be activated by heat, on the reinforcement plate, c) placing the laminate made of adhesive film and reinforcement plate with the adhesive film side on the flexible circuit board, d) introducing the component made of reinforcement plate, adhesive film, and flexible circuit board into a partial vacuum atmosphere, e) hot laminating the component with application of pressure and heat.

The invention relates to a method for adhesive-bonding flexible printed circuit boards to polymer materials for partial or complete stiffening. Heat-activatable foils are used for the adhesive-bonding process.

Pressure-sensitive adhesive tapes and heat-activatable adhesive tapes are processing aids that have been widely used in the industrial era. These adhesive tapes are subject to very stringent requirements in particular when used in the electronics industry. The electronics industry is currently moving toward components that are increasingly thin and light and that can give increased speed of operation. Achievement of these aims demands not only constant further optimization of the production processes but also the use of particular technologies. These developments are also impinging on the flexible printed circuit boards that are very frequently used for providing electrical connection between individual electronic components, e.g. displays, cameras, rigid circuit boards, or keyboards. Said flexible printed circuit boards are also increasingly not merely providing electrical connection but also replacing conventional printed circuit boards, with processors provided thereon.

Flexible printed circuit boards are therefore found in a wide variety of electronic devices, e.g. mobile telephones, automobile radios, computers, etc. They usually consist of layers of copper (electrical conductor) and polyimide (electrical insulator). However, flexible printed circuit boards also require partial or complete reinforcement in order to meet the requirements of the application sector. By way of example, this can be undertaken at locations where the flexible printed circuit board is provided with processors. Reverse-side stiffening is desirable here in order to ensure that the processors do not separate from, or are not broken away from, the very flexible printed circuit board. It is also preferable to undertake stiffening at plug connections. Here again, reverse-side stiffening is provided, in order to increase ease of handling, or, if the printed circuit board has a socket element, also in order to prevent separation thereof.

Heat-activatable adhesive tapes are generally used for adhesive bonding of the flexible printed circuit boards, these being tapes which do not liberate volatile constituents and which can be used even when temperatures are high. This requirement results from the downstream processes known as reflow oven processes (reflow soldering processes), which are used by way of example in order to solder the processors on the flexible printed circuit board.

Examples of heat-activatable adhesive tapes are described by way of example in U.S. Pat. No. 5,478,885, these being based on epoxidized styrene-butadiene and, especially, styrene-isoprene block copolymers. WO 96/33248 reveals other examples of heat-activatable adhesive foils.

The temperature-resistance mentioned and the low emission level are not the only requirements placed upon the adhesive bond: the intention is to minimize the number of air bubbles included between the stiffening medium (“reinforcement sheet”) and the flexible printed circuit board. In subsequent reflow oven processes, air bubbles would cause expansion which would disrupt the adhesive bond between the stiffening medium and the flexible printed circuit board. Air bubbles moreover lead to unevenness on the surface of the printed circuit board and also of the stiffening medium. This can cause problems by way of example when the flexible printed circuit board has to function as plug, in which case partial disruption of electrical contact can occur.

In order to eliminate said problems, a heated press is generally used nowadays for the adhesive bonding process. An advantage of the heated press is that high pressure and high temperature are applied simultaneously. The high pressure achieves good wetting by the heat-activatable adhesive mass on the flexible printed circuit board and on the stiffening medium. The high pressures moreover suppress emissions from the printed circuit board, in particular of moisture. (Polyimide is highly susceptible to water absorption.) However, said process also has disadvantages. By way of example, the efficiency of the process is relatively poor because the process is not carried out continuously and the residence time in the heated press is relatively long (usually at least 90 sec). This is restrictive because the relatively long process time limits the number of flexible printed circuit boards processed per hour. This runs counter to the increasing demand for electronic components and devices.

There is therefore a need for a more efficient process for adhesive bonding of flexible printed circuit boards to stiffening media by use of heat-activatable adhesive systems.

This object is achieved via a method for producing printed circuit boards, encompassing a process for modifying a flexible printed circuit board in particular for stabilizing the same, characterized by at least the following steps:
a) providing a sheet (“reinforcement sheet”) with flexibility lower than that of the flexible printed circuit board,
b) heat-laminating a heat-activatable adhesive foil on the reinforcement sheet,
c) placing, on the flexible printed circuit board, the adhesive-foil side of the laminate made of adhesive foil and reinforcement sheet,
d) introducing the component made of reinforcement sheet, adhesive foil, and flexible printed circuit board into an atmosphere in which the pressure is subatmospheric,
e) heat-laminating the component with application of pressure and heat.

It is advantageous that the heat-laminated component is subjected subsequently to postcuring in a further step f), in particular in an oven.

It is preferable that, prior to lamination to the reinforcement sheet, the heat-activatable adhesive foil is provided with a temporary backing (release paper, release foil, release liner, or the like). This temporary backing can advantageously then be removed after lamination of the heat-activatable adhesive foil to the reinforcement sheet in step b), thus releasing that surface of the heat-activatable adhesive foil that faces away from the reinforcement sheet.

Within the process described it is moreover advantageously possible to undertake punching operations in order to alter dimensions, and by way of example this can take the form of a dimensioning process between steps b) and c), between steps c) and d), or after step f).

It is moreover particularly advantageous that steps c) and d) proceed within a continuous, quasi-continuous, or semicontinuous process.

The steps of the process of the invention are described in detail below, with reference to the materials that are to be used with particular advantage in the invention.

It is advantageous that steps a) to f) of the process of the invention proceed in the sequence stated above; however, it is also possible advantageously to vary the sequence of the steps in the invention. It is also advantageously possible in the invention to carry out two or more steps simultaneously, for example steps d) and e), in that the atmosphere in which the pressure is subatmospheric is created during the heat-lamination process (step e), rather than previously.

In the invention it is particularly advantageous that steps d) and e) are carried out within a continuous process, in particular in that step e) of heat-lamination is carried out with retention of the atmosphere in which the pressure is subatmospheric, and the pressure conditions realized here can be kept constant, but can also be varied.

### Provision of a Heat-Activatable Foil

Heat-activatable adhesive foils are used in the method of the invention. In one highly advantageous embodiment, these adhesive foils are sheets which have no backing and are composed of a heat-activatable adhesive mass, if appropriate with suitable additives. In the invention it is also advantageously possible to use heat-activatable adhesive foils which have a backing. For the purposes of the present invention, by way of example, it is possible to use chemically reacting (binding) adhesive foils or else physically binding adhesive foils. The adhesive foils used can advantageously be to some extent self-adhesive at room temperature, but another advantageous embodiment of the invention uses adhesive foils which are non-tacky at room temperature. However, a feature common to all of the heat-activatable adhesive foils used in the invention is that, above a (foil-specific) activation temperature (or above a corresponding temperature range), they have adequate tack to permit the necessary adhesive-bonding process brought about by the lamination procedure. Very advantageously suitable adhesive foils are those which bring about long-lasting adhesive bonding of the adhesive-bonded substrates (flexible printed circuit board and reinforcement foil) after the method of the invention has been used. The abovementioned postcuring process can in particular be advantageous for achieving long-lasting adhesive bonding (as a function of foil material and foil constitution).

The heat-activatable foil is advantageously a foil based on a mixture of reactive resins which can crosslink at room temperature and form a high-strength three-dimensional polymer network, and on elastomers which have long-lasting elastic properties and which inhibit embrittlement of the product.

Further components can be present, but in the simplest—and most advantageous—case the constitution of the foil is restricted to the abovementioned components.

When the material is heated, the viscosity is briefly reduced, and the material can therefore provide very good wetting of the surface of the flexible printed circuit board.

The constitution of the adhesive foil can advantageously be varied widely by altering the raw materials used in terms of type and proportion.

The elastomer can preferably derive from the group of the polyolefins, polyesters, polyurethanes, or polyamides, or can be a modified rubber, e.g. nitrile rubber.

The particularly preferred thermoplastic polyurethanes (TPUs) are known to be reaction products derived from polyester polyols or polyether polyols and from organic diisocyanates, such as diphenylmethane diisocyanate. Their structure is composed mainly of linear macromolecules. Materials of this type are mostly available commercially in the form of pelletized elastic materials, for example as “Desmocoll” from Bayer AG.

The softening point of the adhesive foil can be reduced sufficiently by combining TPU with selected compatible resins (i.e. admixture of the appropriate resins to the elastomer). In parallel with this, there is an increase in adhesion. Examples of resins that have proven to be advantageously suitable in the invention are colophony resins, hydrocarbon resins, and/or coumarone resins.

The addition of the reactive resin/hardener systems here also leads to a reduction in the softening point of the abovementioned polymers, and this advantageously reduces the processing temperature and processing speed thereof.

The amount of the resins within the elastomer here has to be appropriate for the desired properties of the resultant material, but admixtures of from 2 to 75% by weight, in particular up to 40% by weight, of resin have proven in particular to be highly advantageous.

In one advantageous procedure, the reduction of the softening point of the adhesive foil can be achieved by combining TPU with selected epoxy resins, in particular epoxy resins based on bisphenol A and/or bisphenol B, preferably with addition of a hardener suitable for epoxy systems (an example being dicyandiamide or any other hardener known for epoxys). In particular, an adhesive foil made of this type of system (TPU and the abovementioned epoxy resins) permits good postcuring of the adhesive bond when the adhesive-bonded flexible printed circuit board is by way of example passed through a reflow oven.

The chemical crosslinking reaction of the resins achieves high strengths between the adhesive film and the material to be stiffened.

Another system that is very suitable as adhesive foil in the invention is the system made of TPU and of phenolic resins, if appropriate with further components or additives. In one advantageous procedure of the invention, hardener systems for phenolic resins are also added to the TPU-phenolic-resin-based adhesive foil. It is possible to use here any of the hardeners that are known to the person skilled in the art and that lead to a reaction with the phenolic resins. This category includes by way of example all of the formaldehyde donors, e.g. hexamethylene tetramine.

In another variant preferred in the invention, the heat-activatable foil is based on at least one nitrile rubber.

Examples of nitrile-butadiene rubbers suitable in the invention are obtainable as Europrene™ from Eni Chem, as Krynac™ and Perbunan™ from Bayer, or as Breon™ and Nipol N™ from Zeon. Hydrated nitrile-butadiene rubbers are obtainable as Therban™ from Bayer, and as Zetpol™ from Zeon. Nitrile-butadiene rubbers are polymerized at either high or low temperature.

The acrylonitrile content of the nitrile rubbers is preferably from 15 to 45% by weight, in order to avoid complete phase separation when the reactive resins are used.

Another criterion for the nitrile rubber is the Mooney viscosity. High flexibility at low temperatures has to be ensured, and the Mooney viscosity should therefore be below 100 (Mooney ML 1+4 at 100° C.; corresponding to DIN 53523). An example of nitrile rubbers of this type which is available commercially and has good suitability in the invention is Nipol™ N917 from Zeon Chemicals.

Carboxy-, amine-, epoxy-, or methacrylate-terminated nitrile-butadiene rubbers can advantageously be used as components in addition to the nitrile rubbers. It is particularly preferable to use elastomers of this type with molar mass M_{w}<20 000 g/mol and/or with acrylonitrile content of from 5 to 30% by weight. Acrylonitrile content of at least 5% leads to ideal miscibility.

An example of terminated nitrile rubbers of this type which is available commercially is Hycar™ from Noveon.

As far as carboxy-terminated nitrile-butadiene rubbers are concerned, the rubbers used preferably have a carboxylic acid number of from 15 to 45, very preferably from 20 to 40. The carboxylic acid number is stated as a value in milligrams of KOH, this value being the amount required for complete neutralization of the carboxylic acid, based on 1 g of rubber.

As far as amine-terminated nitrile-butadiene rubbers are concerned, the rubbers used particularly preferably have an amine value of from 25 to 150, more preferably from 30 to 125. The amine value is based on the number of amine equivalents, determined via titration against HCl in ethanolic solution. The amine value here is based on amine equivalents per gram of rubber.

The proportion of the reactive resins in the nitrile-rubber-based heat-activatable adhesive is preferably from 30 to 75% by weight.

One very preferred group encompasses epoxy resins. The molar mass M_{w} of the epoxy resins used preferably varies from 100 g/mol to at most 10 000 g/mol for polymeric epoxy resins.

The epoxy resins used here encompass by way of example the reaction product of bisphenol A and epichlorohydrin, the reaction product of epichlorohydrin and glycidyl ester, and/or the reaction product of epichlorohydrin and p-aminophenol.

Examples of preferred commercially available epoxy resins particularly suitable in the invention are Araldite™ 6010, CY-281™, ECN™ 1273, ECN™ 1280, MY 720, RD-2, from Ciba Geigy, DER™ 331, DER™ 732, DER™ 736, DEN™ 432, DEN™ 438, DEN™ 485 from Dow Chemical, Epon™ 812, 825, 826, 828, 830, 834, 836, 871, 872, 1001, 1004, 1031 etc. from Shell Chemical and HPT™ 1071, HPT™ 1079, likewise from Shell Chemical.

Examples of commercially available aliphatic epoxy resins that are advantageous in the invention are vinylcyclohexane dioxides, such as ERL-4206, ERL-4221, ERL 4201, ERL-4289, or ERL-0400, from Union Carbide Corp.

Examples of novolak resins that can be used, as likewise being very suitable as resins for nitrile rubbers in the invention, are Epi-Rez™ 5132 from Celanese, ESCN-001 from Sumitomo Chemical, CY-281 from Ciba Geigy, DEN™ 431, DEN™ 438, Quatrex 5010 from Dow Chemical, RE 305S from Nippon Kayaku, Epiclon™ N673 from DaiNipon Ink Chemistry, or Epicote™ 152 from Shell Chemical.

Other resins that can also be used with preference as reactive resins for the abovementioned heat-activatable adhesive systems are melamine resins, e.g. Cymel™ 327 and 323 from Cytec.

Examples of other reactive resins that can advantageously be used for the adhesive systems mentioned in the invention are polyisocyanates, e.g. Coronate™ L from Nippon Polyurethan Ind., Desmodur™ N3300 or Mondur™ 489 from Bayer.

The design of the reactive resins should preferably be such as to avoid any liberation of volatile constituents during the crosslinking process.

In one advantageous embodiment of the heat-activatable foil (not only for TPU systems and nitrile rubber systems but also for other systems), (tackifying) resins that increase adhesion are also added, the proportion of these being very advantageously up to 30% by weight, based on the entire constitution of the heat-activatable adhesive. Tackifying resins that can be added are, without exception, any of the adhesive resins that have been disclosed and are described in the literature. Mention may be made of the following in a representative capacity: the pinene resins, indene resins, and colophony resins, and their disproportionated, hydrogenated, polymerized, and esterified derivatives and salts, the aliphatic and aromatic hydrocarbon resins, terpene resins, and terpene-phenol resins, and also C5 and C9 hydrocarbon resins, and also other hydrocarbon resins. It is also possible to use a combination of these and other resins in order to adjust the properties of the resultant adhesive mass in the manner desired. In general terms it is possible to use any of the (soluble) resins that are compatible with the nitrile rubbers, and particular reference may be made to all of the aliphatic, aromatic, or alkylaromatic hydrocarbon resins, hydrocarbon resins based on pure monomers, hydrogenated hydrocarbon resins, functional hydrocarbon resins, and natural resins. Express reference may be made to the description of the current state of knowledge in “Handbook of Pressure Sensitive Adhesive Technology” by Donatas Satas (van Nostrand, 1989).

In order to accelerate the reaction between the two components, it is also optionally possible to add crosslinking agents and accelerators to the mixture, but again these should advantageously avoid liberation of any volatile constituents during the crosslinking process.

Suitable accelerators in the invention are imidazoles, available commercially as 2M7, 2E4MN, 2PZ-CN, 2PZ-CNS, P0505, LOIN from Shikoku Chem. Corp., or Curezol 2MZ from Air Products. Other suitable crosslinking agents are dicyandiamides.

In the invention it is also possible to use amines, in particular tert-amines, for acceleration.

Plasticizers can also be used advantageously in the invention, alongside reactive resins. It is preferably possible here to use plasticizers based on polyglycol ethers, on polyethylene oxides, on phosphate esters, or to use aliphatic carboxylic esters or benzoic esters. It is also possible to use aromatic carboxylic esters, relatively high-molecular-weight diols, sulfonamides, and adipic esters.

It is also possible to add thermoplastics or thermosets as stiffening elements to the elastomer. An example is polyvinyl formal or polyvinyl butyral, or polyvinyl acetate, but there is no intention of any resultant restriction on the formulations suitable in the invention.

It is equally possible to achieve other product properties, such as color or flammability, by using specific additions of dyes or inorganic or organic fillers.

The thickness of the heat-activatable adhesive foil is preferably from 5 to 100 μm, preferably from 10 to 50 μm.

To produce the heat-activatable adhesive foil, the composition that forms the foil is coated in the form of solution or from the melt onto a flexible substrate (“temporary backing” or “release liner”; an example being release foil, release paper) and, if appropriate, dried, so that the composition can readily be removed from the substrate. In one very preferred embodiment, the heat-activatable adhesive foil is also covered with a release liner from above (or by way of example release foil or release paper). This makes it easier to carry out subsequent punching processes, and/or protects the heat-activatable foil from contamination.

### Step a):

### Provision of the Stiffening Material/the Reinforcement Sheet

A wide variety of materials can be used for stiffening (reinforcement). If a stiffening effect is to be exerted on the flexible printed circuit board, it is necessary that the stiffness of the stiffening material is higher than that of the unstiffened, flexible printed circuit board. Use of the expression “reinforcement sheet” is not intended to result in any further restriction of stiffness here.

As the difference in the degree of stiffness between the reinforcement sheet and the flexible printed circuit board increases, the stiffening effect improves. Well-defined products, i.e. stiffened printed circuit boards with well-defined stiffness values, can be produced by way of a specific choice of stiffness of the reinforcement sheet. However, there are in principle no other restrictions on the stiffness values of the stiffening material, and it is therefore possible—as a function of the result desired—to use stiffening materials that have low stiffness values, in order to provide only slight reinforcement of the printed circuit board and thus, for example, realize products that can be rolled up, and it is also possible to use very stiff materials as reinforcement material, in order to obtain very stable final products, for example for pluggable printed circuit boards that have plug-in retention systems (plug contacts) in relation to other components. It is also possible to select, between these values, any value for the stiffness of the reinforcement sheet, in order to achieve a defined stiffness of the product.

Polymer foils are very widely used as stiffening materials. For low-cost stiffening, it is preferable to use polyesters and/or copolyesters. An example that is very often encountered and that has excellent suitability in the invention is PET foils (polyethylene terephthalate foils). The degree of stiffening is in particular determined by the thickness of the polyester foil. Stiffening capability increases as thickness increases. Polyimides or polyethylene naphthalates (PENs) are also very frequently used for stiffening. In comparison with PET, these materials have higher heat resistance for subsequent processes, and therefore likewise have very high suitability for the method of the invention. Examples of other polymer materials which have good suitability in the invention are LCPs (liquid crystal polymers), where these also have very good heat resistance.

In one advantageous variant of the method of the invention, the polymer materials can also take the form of laminates of identical or different polymer foils, in particular of the abovementioned foils, and/or can have functional layers. The laminates mostly have a structure involving adhesives, in order to minimize production costs, but it is also possible to produce the composite by way of other prior-art processes.

In one advantageous variant of the method of the invention, the stiffening polymer foils have been pretreated, e.g. by using prior heat treatment and/or corona treatment and/or prior plasma treatment. The prior heat treatment precludes possible emissions from the subsequent process of the invention. Corona treatment or prior plasma treatment can moreover improve the anchoring of the heat-activatable adhesive foil on the stiffening material.

Other partially organic materials can also be used with advantage in the invention, alongside the polymer materials described by way of example. It is particularly preferable here to use glass fiber/epoxy materials (glass fiber textiles bound with epoxy resin; known as FR-4 materials). In the hardened state, these have high heat resistance, and they have very good stiffening properties. These materials, too, can be pretreated—as described above.

In another advantageous embodiment of the invention, the flexible printed circuit boards can also be stiffened by metal foils or metal sheets. The metal foil or metal sheet here can also assume other functions alongside stiffening, examples being thermal conductivity, and also electrical conductivity. This can be a requirement by way of example for EMI shielding (electromagnetic interference shielding) measures. Suitable metals are steel, including stainless steel, aluminum, brass, bronze, nickel, and/or copper—but no restriction is intended to result from this statement. The metals can moreover also have been provided with a second layer which serves, for example, for passivation. By way of example, gold and/or silver coatings are suitable for this purpose.

In one preferred form, the stiffening material has a roughness (arithmetic average roughness value Rₐ to DIN EN ISO 4287: 1998-10) of Rₐ≦1 μm and/or a layer thickness of from 10 μm to 2 mm, preferably from 50 μm to 800 μm, very preferably from 75 μm to 500 μm.

### Step b):

### Heat-Lamination of the Adhesive Foil to the Reinforcement Sheet

Use is very advantageously made of a heat-activatable foil as described above.

The lamination process in step b) preferably uses a roller laminator. For the purposes of a continuous process and maximum lamination quality, said step is preferably carried out in a heated-roller laminator, i.e. in a laminator where the rollers—or at least some portion of the rollers of the laminator—can be heated. This variant of the method can achieve the highest efficiency of the method. However, as an alternative, it is also possible to carry out this step in a heated press.

If the intention was to provide the heat-activatable foil with two release liners, a first substep is used to remove the protective release liner (i.e. to remove the release liner layer on one of the two sides of the adhesive foil). The stiffening material (the reinforcement sheet) and the heat-activatable foil are then combined in the form of webs. The heated-roller laminator should advantageously have at least one rubber roller. In one particular design of the method of the invention, the heated-roller laminator has two rubber rollers, where these apply the pressure and advantageously the heat for the prelamination process (lamination process in step b). In one preferred design, the heated-roller laminator has two rollers with the same diameter. The rollers are heated, either individually or together, from inside or indirectly. Planar arrangement of the heated rollers is particularly advantageous for efficient lamination. The materials in the form of webs (heat-activatable foil and stiffening material) are combined on what is known as a feeding plate (feeding shelf). This should be in the same plane as the nip of the two rollers. Once the foil has been applied to the reinforcement sheet, the laminated material should advantageously again be passed onward within the same plane (at a height the same as that of the feeding shelf).

The temperature range within which the heat-lamination process is advantageously carried out is from 60° C. to 180° C. (roller temperature). The choice of temperature depends in particular on the heat resistance of the stiffening material, on the thickness of the material, and also on the heat-activatable foil. For efficient conduct of the method, the roller temperature should very preferably be above the softening point of the heat-activatable foil, but still preferably below the crosslinking temperature of the heat-activatable foil, in order to avoid any incipient crosslinking during the prelamination step. It is moreover very preferable to ensure that no bubbles are present after the lamination process. For this, it is advantageous to optimize not only the temperature but also the roller pressure. In one preferred procedure of the invention, the effective pressure (lamination pressure) exerted by the heated-roller laminator on the component to be laminated is at least 15 bar, very preferably at least 25 bar, most preferably at least 30 bar. If there is a requirement to avoid squeezing material out from the adhesive foil (particularly where adhesive foils tend to flow), the effective pressure (lamination pressure) is preferably regulated to a value no higher than 60 bar, more preferably no higher than 50 bar. The respective pressure conditions here are in particular adapted to the properties of the adhesive foil (with a preference to operate at lower pressures if there is a marked tendency to flow under pressure, but selecting a higher lamination pressure if the adhesive foil has little tendency to flow). In order to exclude air bubbles, and for complete wetting, it is advantageous to set the lamination pressure and/or the lamination temperature at the maximum values that can be tolerated by the technology of the method.

In one preferred procedure of the invention, the heated-roller laminator is operated with a process speed of 0.1 to 10 m/min, in particular when conduct of the process is continuous.

This type of advantageous conduct of the process is shown by way of example in the diagram of FIG. 1. At position 1 (unwind), the heat-activatable foil 2, provided with a release liner, is unwound. (The release liner is not shown separately; its location is on that side of the adhesive foil indicated by “2a”.) An optional second release liner layer on the other side of the adhesive foil has either been previously removed prior to wind-up of the foil or is peeled away during the unwind process. (This is not shown here.) The heat-activatable foil is then in contact with the roller 3, by way of the release liner. The stiffening material 5 (reinforcement sheet) is introduced by way of the feeding shelf 4. This can take place batchwise or preferably continuously. The rollers 3, 6 then apply the heat and the pressure. The laminate 7 made of heat-activatable foil 2 (with release liner) and of stiffening material 5 is passed onward by way of the outfeed shelf 8. The heat-activatable foil still has a release liner here and therefore has protection. (This is not shown; the upper side of the adhesive foil in the laminate in the drawing.)

As is shown by way of example in the figure, the lamination process can very preferably proceed by continuously laminating an adhesive foil from the “continuous reel” onto a sequence of a number of, or many, reinforcement sheets passing through the system. An appropriate dimensioning process is then carried out in a subsequent step. This type of continuous conduct of the method is not, of course, restricted to the method specifically shown by way of example in FIG. 1, but can also be used with other modes of lamination.

As an alternative, it is also possible to laminate a “continuous” adhesive foil onto a “continuous” layer made of the reinforcement material, in particular in accordance with the specific method described here and variants thereof. The continuous laminate can then be subjected to a dimensioning process prior to steps d) and e), but can also be laminated to a continuous form of the flexible printed circuit boards in steps d) and e), with subsequent lamination.

The release liner is removed in a step that is subsequent to the heat-lamination process (as in the procedure in FIG. 1 or in any other mode of lamination). In the simplest case, this can be achieved manually. However, in the case of a continuous process it is also possible that this step is achieved by using a delamination roller. It can moreover be advantageous, prior to the removal of the release liner, to undertake one or more punching steps or cutting steps, in order to alter the dimensions of the stiffening material with the heat-activatable foil.

### Step c):

### Placing of the Laminate

After appropriate removal of the release liner, the laminate made of stiffening material and of heat-activatable foil can be applied to the flexible printed circuit board. The side that is applied to the flexible printed circuit board is the side with the heat-activatable foil. The application process can be manual or can use a robot.

Pressure is applied for the placing process, and in the case of non-tacky heat-activatable foils here (those which are not self-adhesive or tacky at room temperature) heat is also applied. In the simplest case, this can be achieved via manual placing and use of a smoothing iron. For a semicontinuous operation, it is also possible to use a heated-roller laminator, by analogy with the specific method in step b). The preconditions described under b) (process parameters, such as pressure and temperature) are then also advantageously applicable here.

An advantageous procedure for the placing process of step c) can also combine layers of a continuous form of the laminate made of heat-activatable foil and stiffening material [for example in the form of product from the continuous lamination process of step b)] with a continuous form of the flexible conductor-track material, and this can in particular take place as stated for step c) above.

### Steps d) and e):

Introduction into an Atmosphere in which the Pressure is Subatmospheric.

### Application of Pressure and Heat

Although it is not strictly correct in physics, the abbreviated term “vacuum” is used below for the atmosphere in which the pressure is subatmospheric.

Various processes can be used to apply vacuum, pressure, and heat (elevated temperature). In one advantageous specific method, a heated-roller laminator is used to apply pressure and heat. In one advantageous variant of the method, a three-part structure can in particular be used.

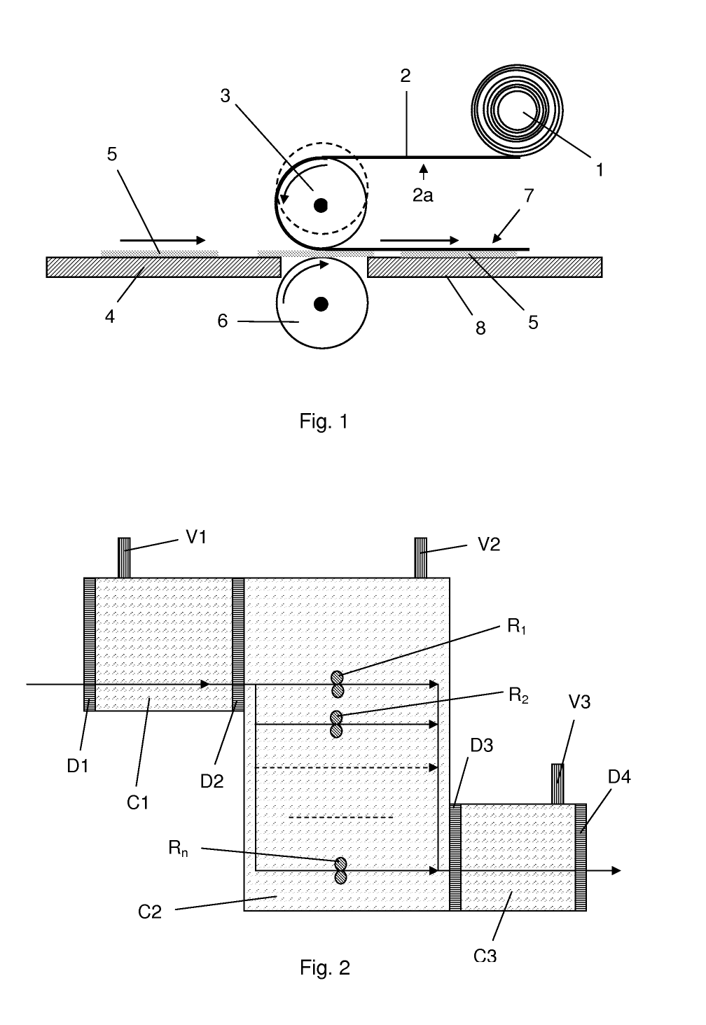

FIG. 2 shows by way of example a diagram of this type of three-part heated-roller laminator apparatus. The flexible printed circuit board with the stiffening material in place is introduced by way of the seal system D1 into the charge chamber C1 (where the arrow indicates the direction of the process). The chamber C1 is then closed and a vacuum is applied by using a vacuum pump V1. The pressure within the vacuum (or correctly within the atmosphere in which the pressure is subatmospheric) is preferably <50 mbar, very preferably <10 mbar, most preferably <1 mbar. The seal system D2 is then opened, and the component made of reinforcement sheet (stiffening material), of adhesive foil, and of flexible printed circuit board is transferred into the heated-roller-laminator chamber C2. The chamber C2 is preferably operated at <50 mbar, very preferably <10 mbar, most preferably <1 mbar (in particular under pressure conditions the same as those selected for the chamber C1; control of vacuum by way of example by use of a vacuum pump V2). The chamber C2 has been supplied with one or more (n) heated-roller laminators (n≧1), so that a plurality of components are introduced in parallel to the lamination process, simultaneously or with only a small delay. Process time can thus be reduced. For practical reasons, it is preferable to use at most six (1≦n≦6) roller laminators, although it would also be possible for the purposes of the invention to use a larger number (n>6) of heated-roller laminators.

The structure of the heated-roller laminators is preferably analogous to the depiction in FIG. 1 and to the relevant description; a factor that has to be taken into account, however, is the relevant difference in the method of introduction of the component to be laminated (absence of unwind and introduction of the component made of reinforcement sheet (stiffening material), of adhesive foil, and of flexible printed circuit board by way of the feeding plate).

In order to achieve complete wetting, the lamination pressure and/or the lamination temperature is generally increased. In one preferred procedure of the invention, the effective pressure (lamination pressure) exerted by the heated-roller laminator on the component to be laminated is at least 15 bar, very preferably at least 25 bar, most preferably at least 30 bar. If there is a requirement to avoid squeezing material out from the adhesive foil (particularly where adhesive foils tend to flow), the effective pressure (lamination pressure) is preferably regulated to a value no higher than 60 bar, more preferably no higher than 50 bar. The respective pressure conditions here are in particular adapted to the properties of the adhesive foil (with a preference to operate at lower pressures if there is a marked tendency to flow under pressure, but selecting a higher lamination pressure if the adhesive foil has little tendency to flow). In order to exclude air bubbles, and for complete wetting, it is advantageous to set the lamination pressure and/or the lamination temperature at the maximum values that can be tolerated by the technology of the method.

The temperature range within which the heat-lamination process is carried out is preferably from 60° C. to 180° C. (roller temperature).

In another preferred procedure, the heated-roller laminator is operated continuously at a process speed in the range from 0.1 to 10 m/min.

Each of the heated-roller laminators Rₙ should have at least one rubber roller; it is advantageous that each heated-roller laminator has two rubber rollers, which apply the pressure and the heat for the prelamination process. Each heated-roller laminator Rₙ advantageously has two rollers with the same diameter. The rollers are heated, either individually or together, from inside or indirectly. Planar arrangement of the heated rollers is particularly advantageous for efficient lamination. After the lamination process, the stiffened printed circuit board is transferred through the seal system D3 out of the chamber C2 into the discharge chamber C3, which has preferably previously been evacuated to <50 mbar, very preferably <10 mbar, most preferably <1 mbar (the pressure being in particular the same as that selected in the chamber C2, where the pressure in the chamber is set by way of example by using another vacuum pump V3). Air is then introduced into the chamber C3 (in particular until standard pressure of 1013 mbar or ambient pressure has been reached), and once the seal system D3 has been closed, and the printed circuit board is then removed, after opening of the seal system D4. The three-part structure permits semicontinuous operation of the system. During removal from chamber C3 it is possible, in parallel, by way of example, to charge material to the chamber C2 and/or C1. Cycle times can therefore be reduced to respectively at most 15 s per chamber C1, C2, and C3, thus ensuring rapid and efficient conduct of the process.

The method presented here can provide particularly advantageous sequential lamination of predimensioned components.

### Variants; in Particular for Steps d) and e)

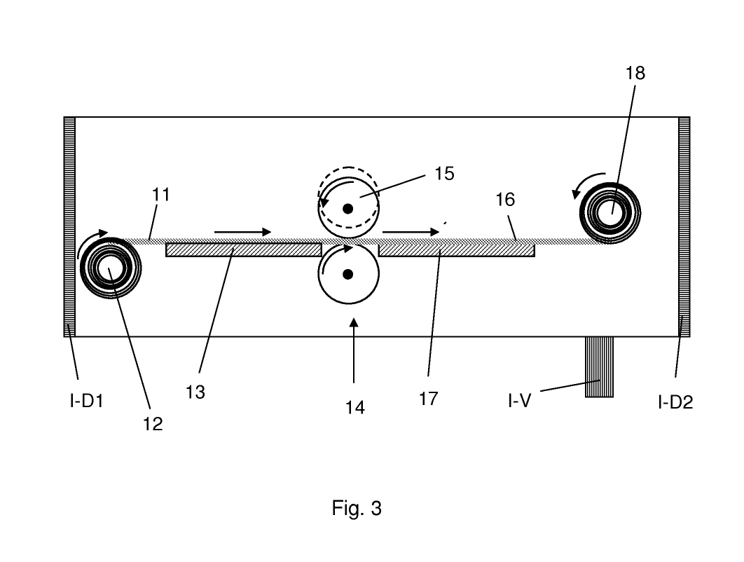

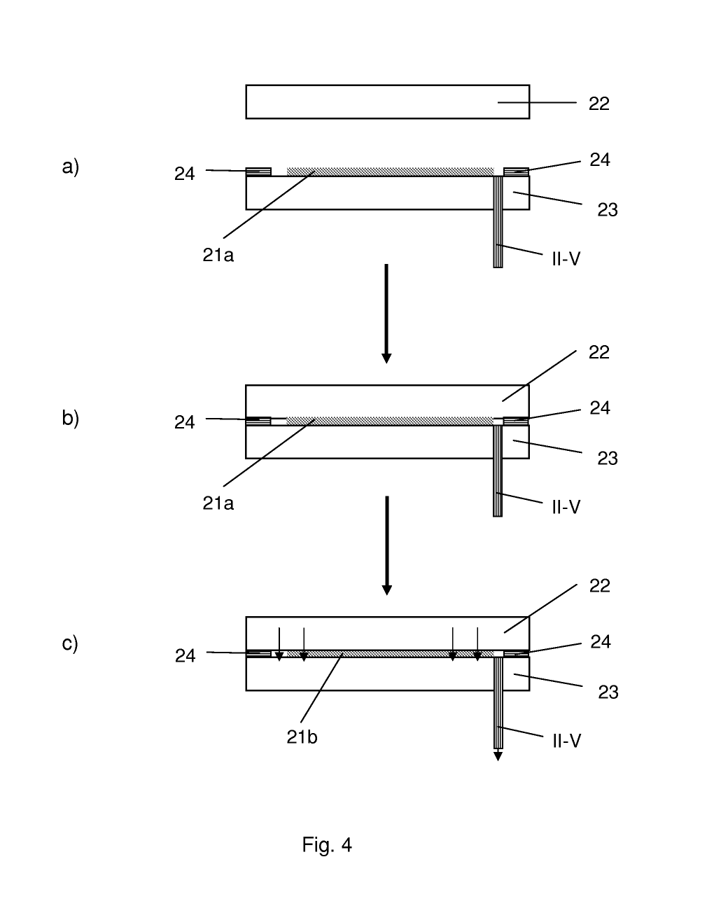

Two variants of the method are presented below. The lamination methods presented below (alternatives as in FIGS. 3 and 4) can in particular be used as alternatives to the procedures presented above for steps d) and e). For step b) it is possible to proceed as described above, but as an alternative for step b) it is also possible to use a laminator as in one of the variants below (corresponding to the variant selected for steps d) and e)), but there is for step b) no need for a controlled atmosphere.

The other steps can advantageously be carried out entirely analogously to the procedure described above.

### Variant 1: Vacuum Heated-Roller Laminator

FIG. 3 shows a vacuum heated-roller laminator. Material is first charged to the vacuum heated-roller laminator by way of the seal system I-D1. The material 11 to be laminated [layer sequence made from flexible printed circuit board, as in the layer-combination (placing) process of step c); in particular in the form of continuous variant] is introduced into the laminator. The material is preferably introduced in roll form, particularly if the flexibility of the stiffening material is sufficient to permit wind-up to give the roll 12 (or more correctly: Archimedean spiral). The chamber is then closed by way of the seal system I-D1 (the removal seal system I-D2 having also been closed), and is evacuated by way of the vacuum pump 1-V. The vacuum (atmosphere in which the pressure is subatmospheric) is preferably set at <50 mbar, very preferably <10 mbar, most preferably <1 mbar. The material 11 is then unwound from the roll 12 and passed by way of the infeed shelf 13 to the actual heated-roller laminator 14. At least one roller 15 of the heated-roller laminator should be adjustable. The laminator 14 achieves a continuous lamination process, in particular by introducing pressure and heat through the laminator rollers.

In one preferred procedure of the invention, the lamination pressure in the heated-roller laminator is at least 15 bar, more preferably at least 25 bar, most preferably at least 30 bar; however—as a function of the adhesive foil used—the procedure is particularly such as to avoid exceeding an upper lamination pressure limit of 60 bar, preferably of 50 bar. Complete wetting can advantageously be achieved by using increased values of lamination pressure and/or lamination temperature.

It is further preferable that the heated-roller laminator is operated continuously with a process speed of from 0.1 to 10 m/min.

The temperature range within which the heat-lamination process is carried out is preferably from 60° C. to 180° C. (roller temperature).

The laminated material 16 is then discharged from the laminator 14 by transfer across the outfeed shelf 17 and is preferably wound up again to give the roll 18 (more correctly: to give the Archimedean spiral). Once the lamination process has been concluded, air is introduced (at standard pressure or ambient pressure) by way of the seal system I-D2 into the entire chamber, and the material is removed by way of the seal system I-D2. Material can be charged at the same time by way of the seal system I-D1 for a further lamination process.

The heated-roller laminator should advantageously have at least one rubber roller. In one further design, the heated-roller laminator has two rubber rollers, where these apply the pressure and the heat for the lamination process. In one preferred design, the heated-roller laminator has two rollers with the same diameter. The rollers are heated, either individually or together, from inside or indirectly. Planar arrangement of the heated rollers is particularly preferred for efficient lamination.

### Variant II: Vacuum Plate Laminator

This variant shown by way of example in the diagram of FIG. 4 is particularly suitable for the lamination of dimensioned components.

In a first step [step II-a), corresponding to FIG. 4a)], the flexible printed circuit board is inserted into the plate laminator with one or more stiffening materials, each of which has an adhesive-foil layer (reference sign 21a in FIG. 4a indicates the as yet unlaminated composite made of flexible printed circuit board and reinforcement material). The plate laminator consists of two metal plates 22 and 23, at least one, but preferably both, of the metal plates 22, 23 being heatable. One metal plate 23 moreover has one or more seals 24, so that it is possible to generate a vacuum within the apparatus when it is closed, and at least one metal plate 23 has been equipped with at least one aperture which permits evacuation (vacuum pump II-V). (In contrast to the diagram, this can also be the metal plate 22.) The flexible printed circuit board with the stiffening material (composite 21a) is placed within the evacuatable region formed by the seal(s) 24. In step II-b), corresponding to FIG. 4b), the chamber formed by the seal(s) 24 is then closed, in particular by lowering the metal plate 22. In step II-c), corresponding to FIG. 4c), the metal plates 22, 23 are then drawn together by evacuation by the vacuum pump II-V. This firstly removes air bubbles from the heat-activatable foil used for the adhesive-bonding process and secondly applies pressure to the composite 21a to be laminated, through the metal plates 22, 23, so that the lamination process produces the composite 21b. The pressure to be exerted for the lamination process can be regulated appropriately by way of the selected seal(s) 24 (and in particular via the height and stiffness of the seals). The heat necessary for the lamination process and for activating the heat-activatable foil is moreover introduced through the at least one heatable metal plate (22 and/or 23).

The process is preferably operated with a vacuum (atmosphere in which the pressure is subatmospheric) of <50 mbar, very preferably <10 mbar, most preferably <1 mbar. For a rapid process it is preferable that both metal plates (22, 23) are heatable. The temperature of the metal plates is preferably from 60 to 250° C., very preferably from 130 to 200° C. The lamination pressure selected is preferably at least 15 bar, more preferably at least 25 bar, most preferably at least 30 bar; however—as a function of the adhesive foil used—the procedure is particularly such as to avoid exceeding an upper lamination pressure limit of 60 bar, preferably of 50 bar. The process times depend on the constitution of the heat-activatable foil (speed of crosslinking), and also on the period required for evacuation. In one most preferred process, the maximum vacuum is achieved within a period of 45 s, very preferably within a period of 30 s, and preferably within a period of 15 s. At constant vacuum, the pressure through the metal plates (22, 23) can be kept constant until air is then in turn introduced. Once air has been introduced, the laminated printed circuit boards with the stiffening material (laminated composite 21b) are removed.

Further modification of this process is advantageously possible. By way of example, the seal (24) can be replaced by a diaphragm which covers the entire area and which firstly assumes the sealing function but also presses the printed-circuit-board composite onto the upper metal plate. Very uniform pressure is applied here to the composite, because of the flexible character of the material. In this instance, evacuation is preferably achieved from the upper metal plate (22); in particular, the heating is also achieved by means of said metal plate (22). Pressure is applied to the lower metal plate (23) in order to achieve closure before the vacuum is applied and before the pressure is exerted on the flexible printed circuit board with the stiffening material (composite 21).

### Step f):

### Postcuring: in Particular in an Oven

In order to achieve maximum adhesive-bond strength of stiffening material on the flexible printed circuit board, it is advantageous to harden the heat-activatable adhesive mass completely. The hardening process can by way of example take place in an oven. In one preferred procedure of the invention, the oven is operated with convection. The temperature is preferably from 100° C. to 230° C.—as a function of the hardening temperature of the heat-activatable adhesive mass, which should be used as a criterion for appropriate selection of process temperature.

In one preferred variant, the laminate made of flexible printed circuit board and of stiffening material is not hardened by using a constant temperature, but instead by using a temperature gradient. By way of example, heating at 70° C. is first used, then heating at 110° C., and then heating at 150° C. Use of this specific method can, if appropriate, also provide non-aggressive drying of the flexible printed-circuit-board materials, and also of the stiffening materials, in order to avoid formation of bubbles, which by way of example could derive from water vapor from polyimide, within the adhesive-bonded joint (in particular within and/or on the adhesive foil included in the lamination process, i.e. within the “joint” between flexible printed circuit board and reinforcement sheet). As an alternative to this procedure for the drying and curing process, continuous temperature gradients are also suitable, as well as stepwise processes.

The process time in the oven is preferably from 10 minutes to 12 hours, as a function of the chemical constitution and hardening mechanism of the heat-activatable foil.

By repeating the process sequence, the method of the invention can also be used to provide flexible printed circuit boards with a plurality of reinforcement sheets, and to produce a corresponding multilayered laminate (having two, three or more reinforcement layers).

### Experimental Section

In order to validate the suitability of the process of the invention for achieving the object of the invention, adhesive bonding was carried out with the commercially available product tesa 8865®. This heat-activatable foil is based on a combination of nitrile rubber and epoxy resin.

The stiffening material (reinforcement sheet) used was either a polyimide foil of thickness 75 μm or else, in a second experiment, a glass fiber/epoxy sheet of thickness 300 μm. The printed circuit boards used were flexible polyimide-copper laminates. The laminators corresponded to the arrangement in FIG. 1 in step a) and, respectively, to the arrangement in FIG. 2 with laminators corresponding to FIG. 1 in steps d) and e), and were operated at 170° C. with an effective adhesive-bonding pressure of 20 bar, and with a speed of 1 m/min. In all instances the vacuum was smaller than 10 mbar. The postcuring process in the oven was carried out at 70° C. for 10 minutes, at 110° C. for 10 minutes, and at 150° C. for 10 minutes.

The adhesive bonds obtained from the various embodiments of the process of the invention were free from bubbles. A microscope (10× magnification) was used to evaluate the adhesive bond in terms of freedom from bubbles. Even after a reflow-oven process (simulation test: 5 minutes at 260° C. in a convection oven), no bubbles formed within the adhesive-bonded joint.

1. A method for producing printed circuit boards, encompassing a process for modifying a flexible printed circuit board comprising the following steps:
a) providing a reinforcement sheet with flexibility lower than that of the flexible printed circuit board,
b) heat-laminating a heat-activatable adhesive foil on the reinforcement sheet,
c) placing the adhesive-foil side of the laminate made of adhesive foil and reinforcement sheet on the flexible printed circuit board,
d) introducing the component made of reinforcement sheet, adhesive foil, and flexible printed circuit board into an atmosphere in which the pressure is subatmospheric, and
e) heat-laminating the component with application of pressure and heat.

2. The method according to claim 1, wherein steps d) and e) are carried out within a continuous process.

3. The method according to claim 1 wherein the pressure p in the atmosphere in which the pressure is subatmospheric is <50 hPa.

4. The method according to claim 1 wherein at least step e) is carried out in at least one laminator.

5. The method according to claim 1 wherein the temperature range within which the heat-lamination process is carried out in step e) is from 60° C. to 180° C.

6. The method according to claim 1 wherein the lamination pressure to which the component is exposed during the heat-lamination process in step e) is at least 15 bar.

7. The method according to claim 6 wherein the lamination pressure during the heat-lamination process in step e) is not more than 60 bar.

8. The method according to claim 1 comprising post-curing the component after the heat lamination step.

9. The method according to claim 8 wherein the post-curing is achieved by introducing the component into an oven.

10. The method according to claim 1 wherein the area expansion values of the reinforcement sheet are the same as those of the flexible printed circuit board.

11. The method according to claim 3 wherein the pressure p in the atmosphere in which the pressure is subatmospheric is <10 hPa.

12. The method according to claim 11 wherein the pressure p in the atmosphere in which the pressure is subatmospheric is <1 hPa.

13. The method according to claim 7 wherein the lamination pressure during the heat-lamination process in step e) is between about 30 to 60 bar.
